(19) United States
(12) Patent Application Publication
(10) Pub. No.: US 2026/0291460 A1
(43) Pub. Date: Sep. 24, 2026

(54) MAGNETOSTATIC WAVE RESONATOR BASED SCANNING FILTER

(71) Applicant: BAE Systems Information and Electronic Systems Integration Inc., Nashua, NH (US)

(72) Inventors: Bill Zivasatienraj, Nashua, NH (US); Eric D. Langlois, Auburn, NH (US); Michael W. Cason, Brattleboro, VT (US)

(73) Assignee: BAE Systems Information and Electronic Systems Integration Inc., Nashua, NH (US)

(21) Appl. No.: 19/389,476

(22) Filed: Nov. 14, 2025

Related U.S. Application Data
(60) Provisional application No. 63/774,368, filed on Mar. 19, 2025.

(51) Int. Cl. H03H 2/00; H01P 1/217; H03C 7/02

(52) U.S. Cl. CPC H03H 2/001; H01P 1/217; H03C 7/022

(57) ABSTRACT

Magnetostatic wave resonator based scanning filter. A scanning filter implementing the techniques according to an embodiment includes a magnetostatic wave filter configured to filter a signal at a sweeping resonant frequency. The resonant frequency is based on an applied magnetic flux density. The filter also includes a filter modulator comprising a voltage sweep generator configured to generate a periodic time varying voltage, and an electromagnet coupled in series with the voltage sweep generator and configured to generate the magnetic flux density based on a current flow through an inductive component of the electromagnet. The current flow is proportional to the periodic time varying voltage. The magnetostatic wave filter is a planar device comprising a ferrimagnetic material including magnetite, yttrium iron garnet, or rhenium ferrite.

### CROSS-REFERENCE TO RELATED APPLICATIONS

This application claims priority under 35 U.S.C. § 119(e), to co-pending U.S. Provisional Application No. 63/774,368 filed Mar. 19, 2025, titled A MAGNETOSTATIC WAVE RESONATOR-BASED DEVICE FOR ELECTRONIC SPECTRUM SCANNING, which is hereby incorporated herein by reference in its entirety.

### FIELD OF DISCLOSURE

The present disclosure relates to filters, and more particularly to a magnetostatic wave resonator based scanning filter.

### BACKGROUND

Many applications, including military applications, require rapid and continuous scanning of the radio frequency (RF) spectrum, for example to provide robust situational awareness, to implement low probability of intercept communications, and/or to enable complex signal modulation schemes.

### BRIEF DESCRIPTION OF THE DRAWINGS

FIG. 1 illustrates spectrum scanning using a magnetostatic wave filter, in accordance with certain embodiments of the present disclosure.

FIG. 2 is a block diagram of the filter modulator of FIG. 1, configured in accordance with certain embodiments of the present disclosure.

FIG. 3 illustrates inductor charge transients of the electromagnet of FIG. 2, in accordance with certain embodiments of the present disclosure.

FIG. 4 illustrates bias voltage and inductor current for fast scanning, in accordance with certain embodiments of the present disclosure.

FIG. 5 illustrates bias voltage and inductor current for ultra-fast scanning, in accordance with certain embodiments of the present disclosure.

FIG. 6 is a flowchart illustrating a methodology for fabrication of a scanning RF filter, in accordance with an embodiment of the present disclosure.

FIG. 7 is a block diagram of a processing platform configured to operate a scanning RF filter, in accordance with an embodiment of the present disclosure.

Although the following Detailed Description will proceed with reference being made to illustrative embodiments, many alternatives, modifications, and variations thereof will be apparent in light of this disclosure.

### DETAILED DESCRIPTION

Techniques are provided herein for rapid and continuous spectrum scanning using a planar magnetostatic wave resonator filter. As noted above, many applications, including military applications, require rapid and continuous scanning of the RF spectrum, for example to provide robust situational awareness, to implement low probability of intercept communications, and/or to enable complex signal modulation schemes, to name a few. Some RF filters employ banks of parallel digitally tunable bandpass filters. This technique, however, suffers from relatively high insertion losses as the frequencies increase, and the need for additional digital signal processing, while still imposing undesirable limitations on the upper achievable bandwidth.

To this end, and in accordance with an embodiment of the present disclosure, a planar magnetostatic wave resonator filter is presented which employs an electromagnet based filter modulator that is capable of sweeping through the scanning frequency of the resonator at relatively high scan rates, for example up to 1 Petahertz (PHz)/second. The disclosed techniques enable rapid and continuous scanning of the electromagnetic spectrum for both transmit and receive side applications.

In accordance with an embodiment, an RF filter system implementing the techniques for rapid scanning includes a magnetostatic wave filter configured to filter a signal at a sweeping resonant frequency. The resonant frequency is based on an applied magnetic flux density. The system also includes a filter modulator comprising a voltage sweep generator configured to generate a periodic time varying voltage, and an electromagnet coupled in series with the voltage sweep generator. The electromagnet is configured to generate the magnetic flux density based on a current flow through an inductive component of the electromagnet. The current flow is proportional to the periodic time varying voltage generated by the voltage sweep generator. In some embodiments, the magnetostatic wave filter is a planar device comprising a ferrimagnetic material including magnetite, yttrium iron garnet, or rhenium ferrite.

It will be appreciated that the techniques described herein may provide improved spectrum scanning at relatively high sweep rates, compared to other methods that use switched filter banks to switch between center frequencies and fractional bandwidths to cover a spectral region. Numerous embodiments and applications will be apparent in light of this disclosure.

### System Architecture

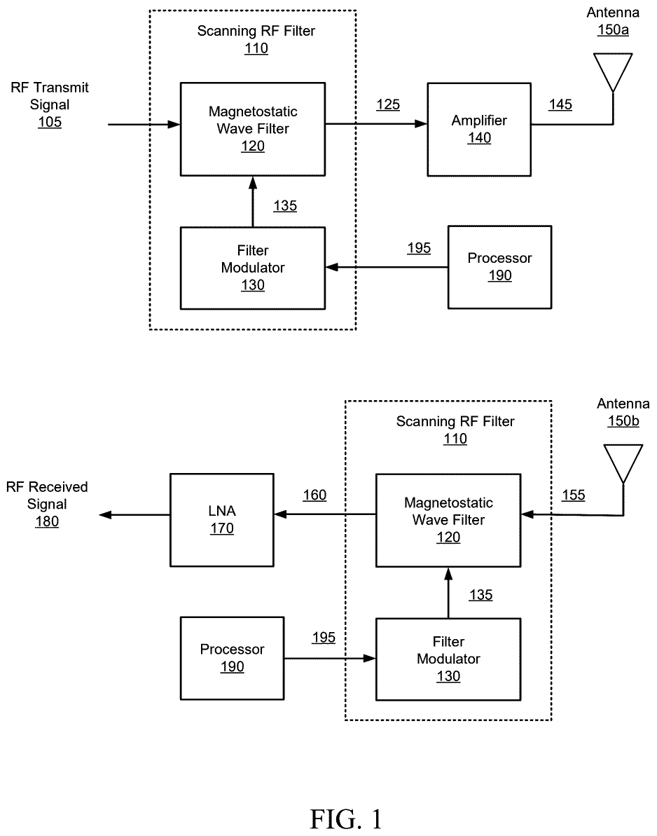

FIG. 1 illustrates spectrum scanning 100 using a magnetostatic wave filter 120, in accordance with certain embodiments of the present disclosure. A scanning RF filter 110 is shown to include a magnetostatic wave filter 120 and a filter modulator 130. The scanning RF filter 110 may be used in a transmit configuration and/or a receive configuration. In the transmit configuration, an RF transmit signal 105 is filtered to generate a filtered signal 125 which is provided to an amplifier 140. The amplified filtered signal 145 may then be transmitted through antenna 150a. In the receive configuration, signals 155 received through antenna 150b are filtered by the scanning RF filter 110 to generate a filtered signal 160. The filtered signal 160 may then be amplified, for example by a low noise amplifier 170, to generate the RF received signal 180, for any suitable further processing. In some embodiments, a processor 190 may be employed to generate sweep parameters 195 to control the filter modulator 130, as will be described in greater detail below.

The scanning RF filter 110 is shown to include a magnetostatic wave filter 120 and a filter modulator 130. The magnetostatic wave filter 120 is configured to filter an input signal (e.g., 105 or 155) at a sweeping resonant frequency. Magnetostatic wave devices are tunable via an applied magnetic bias. The resonant frequency of the device is therefore based on an applied magnetic flux density 135 imparted by a magnetic field which is generated by the filter modulator 130, as described below. As the magnetic flux density 135 sweeps through a range of values, the filter also sweeps through a frequency range, thus scanning the spectrum. The more rapidly the magnetic flux density can be varied by the filter modulator, the more rapidly the filter frequency can be swept.

In some embodiments, the magnetostatic wave filter 120 is a planar device comprising a ferrimagnetic material which may include including magnetite, yttrium iron garnet, or rhenium ferrite. The magnetostatic wave filter 120 (e.g., planar device) may be fabricated as a thin film device having a thickness of less than 10 micrometers, although other configurations are possible.

The use of thin films (e.g., less than 10 micrometers) allows for a reduction of the magnetic gap between the filter 120 and the modulator 130 to less than 0.3 millimeters. A smaller magnetic gap enables higher magnetic flux densities and simplifies the fabrication of thin film surfaces with improved uniformity (e.g., less than one percent overall deviation across the surface area) for improved performance. Planar thin film technology is therefore more responsive to rapid changes in magnetic flux density while maintaining desired RF performance.

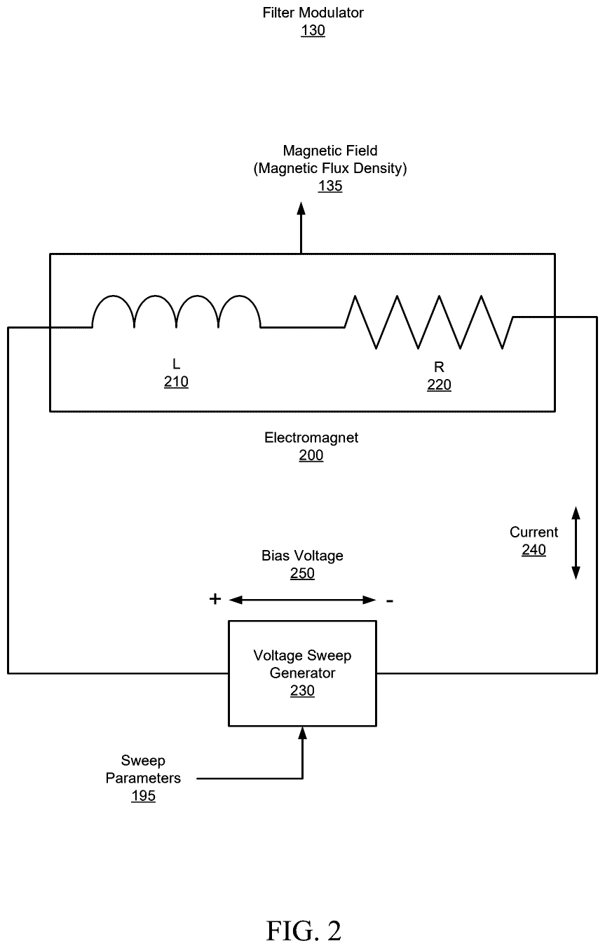

FIG. 2 is a block diagram of the filter modulator 130 of FIG. 1, configured in accordance with certain embodiments of the present disclosure. The filter modulator 130 is shown to include an electromagnet 200 coupled in series with a voltage sweep generator 230.

The voltage sweep generator 230 is configured to generate a periodic time varying bias voltage 250, using any suitable techniques. In some embodiments, the periodic time varying voltage 250 is a non-sinusoidal waveform, for example, a square (or approximately square) waveform. The parameters of the time varying voltage may include amplitude, frequency, and wave shape (e.g., a square wave or other suitable shape). In some embodiments, these sweep parameters may be fixed or otherwise hard-coded into the system design. In some embodiments, the parameters may be programmable and provided as sweep parameters 195, for example, by processor 190.

The electromagnet 200 is shown to include an inductor 210 (having an inductance value L), in series with a resistor 220 (having a resistance value R). The electromagnet 200 is configured to generate the magnetic field having magnetic flux density 135 based on the current flow 240 through the inductor 210 of the electromagnet. As the value of the current flow 240 sweeps, the magnetic flux density 135 sweeps. This allows for rapid scanning, as opposed to tuning to a fixed frequency.

The current flow 240 is proportional to the periodic time varying bias voltage 250 generated by the voltage sweep generator 230. In some embodiments, for example, the inductor current 240 equals the bias voltage 250 divided by the value of the electromagnet resistor R 220.

The planar structure of the magnetostatic wave filter 120 allows for a reduced reluctance air gap between the filter 120 and the modulator 130, providing reduced size and power consumption. In some embodiments, the magnetostatic wave filter 120 is separated from the filter modulator 130 by less than 100 micrometers. In some embodiments, the magnetic flux density 135, generated by the electromagnet 200, is applied in an orthogonal direction relative to the plane of resonance of the magnetostatic wave filter 120.

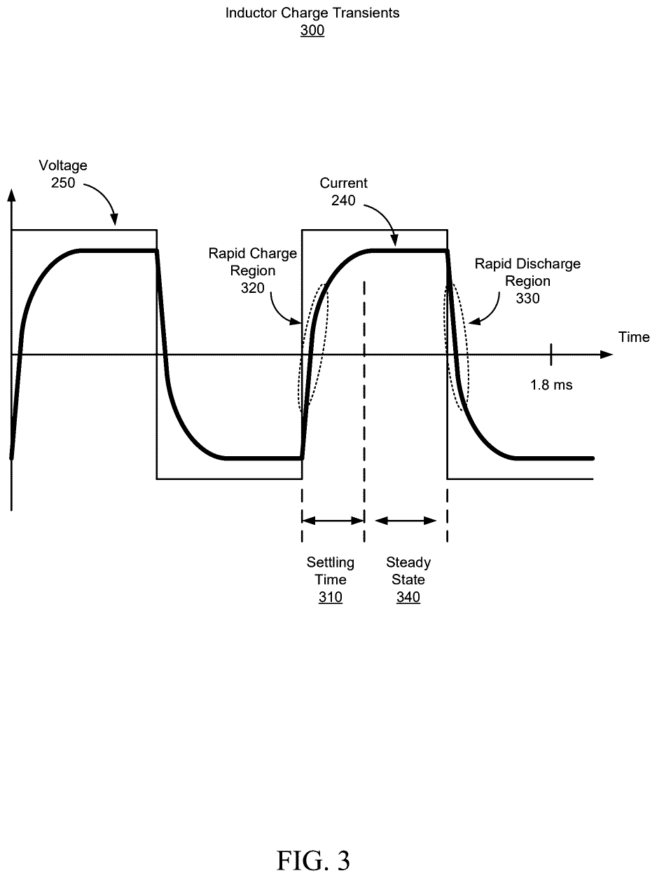

FIG. 3 illustrates inductor charge transients 300 of the electromagnet 200 of FIG. 2, in accordance with certain embodiments of the present disclosure. A current 240 flows through the electromagnet 200 in response to a toggling bias voltage 250 that is generated by the voltage sweep generator 230. The current 240 varies from a maximum steady state value to a minimum steady state value over a settling time 310 of the inductor 210. The settling time 310 is part of the inductor charge transient and (in combination with the steady state region 340) limits the rate at which the tuning of the magnetostatic wave filter 120 can be changed. The settling time 310 is approximately equal to 5 time constants τ, where τ=L/R. The settling time can be decreased and the tuning rate increased by varying the values of L and R, but there are limitations. Decreasing the inductance lowers the magnetic flux density which adversely affects the filter operation. Similarly, increasing the resistance increases the power consumption of the system which is also undesirable.

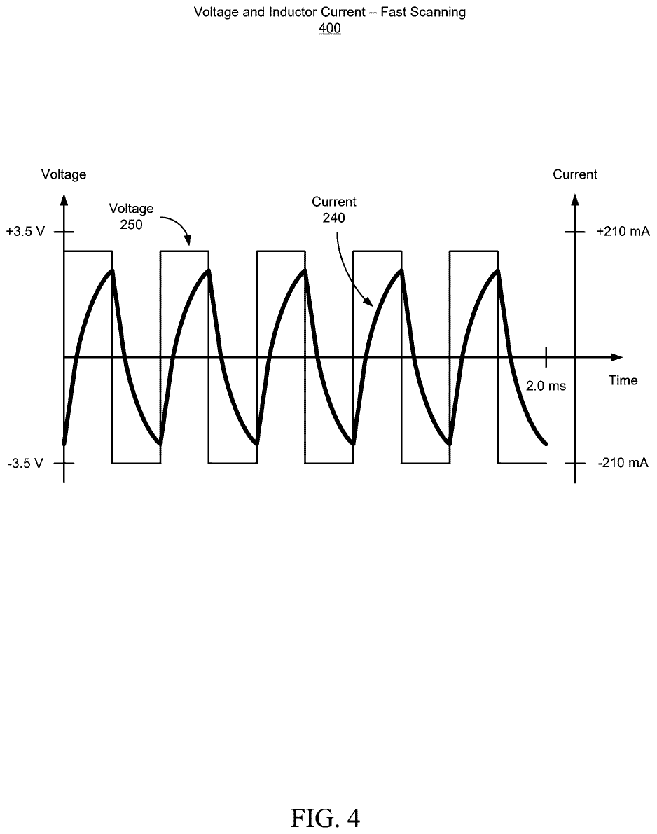

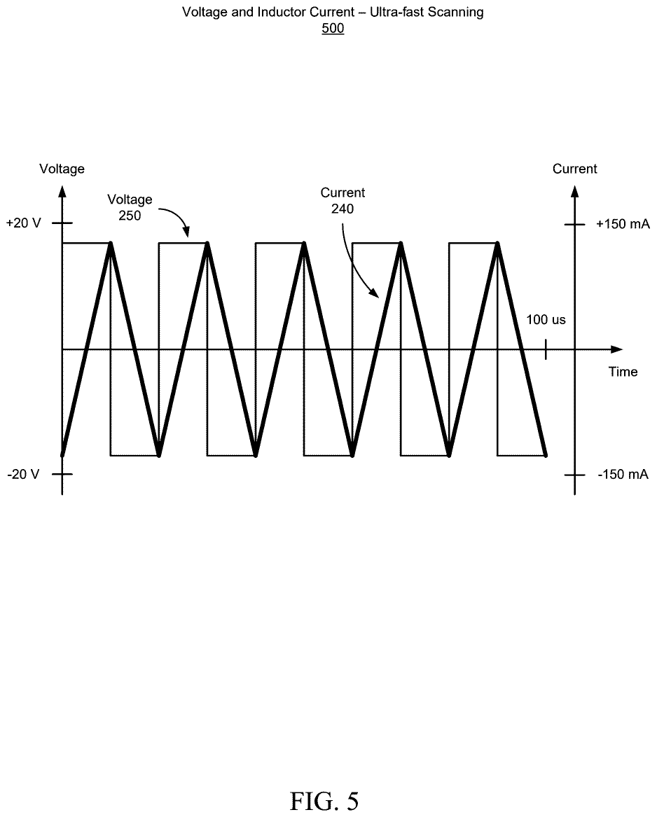

An alternative or additional technique, however, is to limit operation of the inductor to the rapid charge region 320 and rapid discharge region 330. During these periods, as the current 240 is rapidly changing, the magnetic flux density 135 is also rapidly changing. This allows for a faster frequency sweep of the magnetostatic wave filter 120, as described below in connection with FIGS. 4 and 5.

FIG. 4 illustrates bias voltage 250 and inductor current 240 for fast scanning 400, in accordance with certain embodiments of the present disclosure. In this example, the polarity of the bias voltage 250 is switched more rapidly to maintain the sweeping of the inductor current 240 in the rapid charging and discharging regions 320 and 330 rather than letting the current enter the more slowly varying region of the settling time 310 and the steady state region 340. For example, the inductor current goes through five bi-directional sweeps in 2.0 milliseconds, which is faster than the sweep rate shown in FIG. 3.

FIG. 5 illustrates bias voltage 250 and inductor current 240 for ultra-fast scanning 500, in accordance with certain embodiments of the present disclosure. In this example, the polarity of the bias voltage 250 is switched yet more rapidly and to larger amplitudes (e.g., +/−18 volts). This results in a still faster sweep of the inductor current 240. For example, the inductor current goes through five bi-directional sweeps in 100 microseconds. During this time period, the inductor current 240 sweeps from 120 mA to −120 mA in 10 microseconds. If, for example, the magnetostatic wave filter 120 is configured to sweep the resonant frequency by 20 MHz/mA, the scanning RF filter 110 will sweep through 4.8 GHz in 10 microseconds or 480 THz/second (e.g., 4.8×10\hat{ }14 Hz/second). Even higher rates of up to 1 PHz/second are possible by increasing the bias voltage 250 further. Additionally, in some embodiments, N parallel channels of the scanning RF filter 110 may be employed to increase the sweep rate further by a factor of N.

In some embodiments, therefore, the scan rate of the sweeping resonant frequency of the magnetostatic wave filter 120 is based on the rate of change of the magnetic flux density 135. The magnetic flux density 135 in turn is based, at least in part, on the inductance L and the resistance R of the electromagnet 200, the amplitude of the periodic time varying bias voltage 250, and the frequency of the periodic time varying bias voltage 250. In some embodiments, the rate of change of the magnetic flux density 135 may range up to about 1 tesla per microsecond. For example, the magnetic flux density 135 may vary through the range of approximately 0.1 tesla per microsecond to 1.1 tesla per microsecond.

It should be noted that the magnetostatic wave filter 120 is modulated by a non-sinusoidal waveform that is relatively easy to control, since the waveform does not need to be periodic or symmetric. The scan rate may be varied, in some embodiments of the present disclosure, from 1 GHz per microsecond down to 0.001 GHz per microsecond, which can be a useful range for some applications. In comparison, scan rates slower than 0.000001 GHz per microsecond (or 1 MHz per millisecond) fall within the normal operational range of a conventional tunable filter.

### Methodology

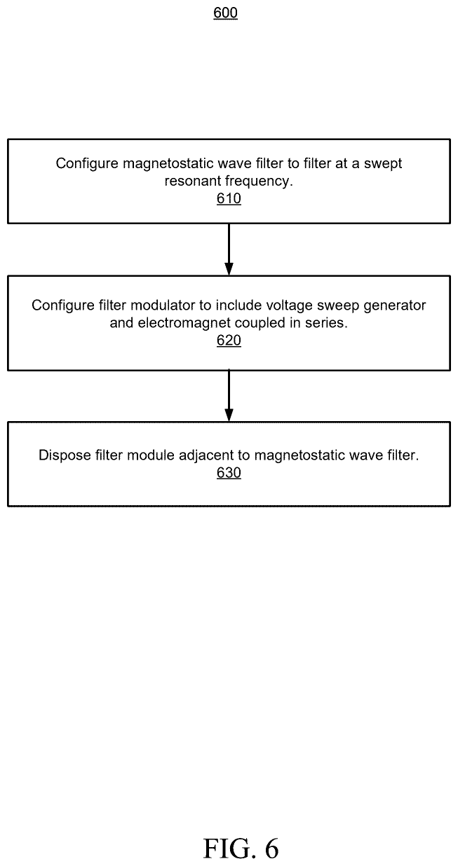

FIG. 6 is a flowchart illustrating a methodology 600 for fabrication of a scanning RF filter, in accordance with an embodiment of the present disclosure. As can be seen, example method 600 includes a number of phases and sub-processes, the sequence of which may vary from one embodiment to another. However, when considered in aggregate, these phases and sub-processes form a process for fabrication of a scanning RF filter 110, in accordance with certain of the embodiments disclosed herein, for example as illustrated in FIGS. 1-5, as described above. However other system architectures can be used in other embodiments, as will be apparent in light of this disclosure. To this end, the correlation of the various functions shown in FIG. 6 to the specific components illustrated in the figures, is not intended to imply any structural and/or use limitations. Rather other embodiments may include, for example, varying degrees of integration wherein multiple functionalities are effectively performed by one system. Numerous variations and alternative configurations will be apparent in light of this disclosure.

In one embodiment, method 600 commences, at operation 610, by configuring a magnetostatic wave filter to filter a signal at a sweeping resonant frequency which is based on an applied magnetic flux density.

At operation 620, a filter modulator is configured to include a voltage sweep generator coupled in series with an electromagnet. The voltage sweep generator is configured to generate a periodic time varying voltage. The electromagnet is configured to generate the magnetic flux density based on a current flow through an inductive component of the electromagnet, which is proportional to the periodic time varying voltage.

At operation 630, the filter modulator is disposed adjacent to the magnetostatic wave filter. In some embodiments, the magnetostatic wave filter is separated from the filter modulator by less than 100 micrometers.

The scan rate of the sweeping resonant frequency is based on the inductance of the electromagnet, the amplitude of the periodic time varying voltage, and the frequency of the periodic time varying voltage.

In some embodiments, additional operations may be performed, as previously described in connection with the system. For example, the magnetostatic wave filter may be fabricated as a planar device comprising a ferrimagnetic material including magnetite, yttrium iron garnet, or rhenium ferrite. In some embodiments, the planar device may be a thin film device having a thickness of less than 10 micrometers.

### Example System

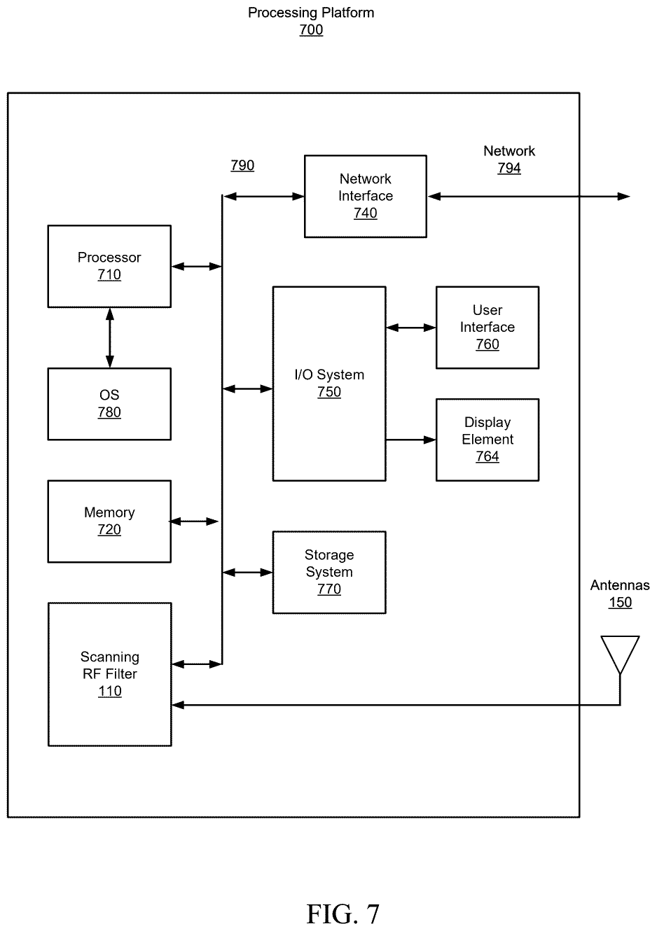

FIG. 7 is a block diagram of a processing platform 700 configured to operate a scanning RF filter 110, in accordance with an embodiment of the present disclosure. In some embodiments, platform 700, or portions thereof, may be hosted on, or otherwise be incorporated into the electronic systems of an aircraft, ship, ground station, or man-portable system deployment.

In some embodiments, platform 700 may comprise any combination of a processor 710, memory 720, a network interface 740, an input/output (I/O) system 750, a user interface 760, a display element 764, a storage system 770, Scanning RF filter 110, and antenna 150. As can be further seen, a bus and/or interconnect 790 is also provided to allow for communication between the various components listed above and/or other components not shown. Platform 700 can be coupled to a network 794 through network interface 740 to allow for communications with other computing devices, platforms, devices to be controlled, or other resources. Other componentry and functionality not reflected in the block diagram of FIG. 7 will be apparent in light of this disclosure, and it will be appreciated that other embodiments are not limited to any particular hardware configuration.

Processor 710 can be any suitable processor, and may include one or more coprocessors or controllers, such as an audio processor, a graphics processing unit, or hardware accelerator, to assist in the execution of mission software and/or any control and processing operations associated with platform 700, including operation of the Scanning RF filter 110. For example, processor 710 may be the same processor as processor 190. In some embodiments, the processor 710 may be implemented as any number of processor cores. The processor (or processor cores) may be any type of processor, such as, for example, a micro-processor, an embedded processor, a digital signal processor (DSP), a graphics processor (GPU), a tensor processing unit (TPU), a network processor, a field programmable gate array or other device configured to execute code. The processors may be multithreaded cores in that they may include more than one hardware thread context (or “logical processor”) per core. Processor 710 may be implemented as a complex instruction set computer (CISC) or a reduced instruction set computer (RISC) processor. In some embodiments, processor 710 may be configured as an x86 instruction set compatible processor.

Memory 720 can be implemented using any suitable type of digital storage including, for example, flash memory and/or random access memory (RAM). In some embodiments, the memory 720 may include various layers of memory hierarchy and/or memory caches as are known to those of skill in the art. Memory 720 may be implemented as a volatile memory device such as, but not limited to, a RAM, dynamic RAM (DRAM), or static RAM (SRAM) device. Storage system 770 may be implemented as a non-volatile storage device such as, but not limited to, one or more of a hard disk drive (HDD), a solid-state drive (SSD), a universal serial bus (USB) drive, an optical disk drive, tape drive, an internal storage device, an attached storage device, flash memory, battery backed-up synchronous DRAM (SDRAM), and/or a network accessible storage device.

Processor 710 may be configured to execute an Operating System (OS) 780 which may comprise any suitable operating system, such as Google Android (Google Inc., Mountain View, CA), Microsoft Windows (Microsoft Corp., Redmond, WA), Apple OS X (Apple Inc., Cupertino, CA), Linux, or a real-time operating system (RTOS). As will be appreciated in light of this disclosure, the techniques provided herein can be implemented without regard to the particular operating system provided in conjunction with platform 700, and therefore may also be implemented using any suitable existing or subsequently-developed platform.

Network interface circuit 740 can be any appropriate network chip or chipset which allows for wired and/or wireless connection between other components of platform 700 and/or network 794, thereby enabling platform 700 to communicate with other local and/or remote computing systems, and/or other resources. Wired communication may conform to existing (or yet to be developed) standards, such as, for example, Ethernet. Wireless communication may conform to existing (or yet to be developed) standards, such as, for example, cellular communications including LTE (Long Term Evolution) and 5G, Wireless Fidelity (Wi-Fi), Bluetooth, and/or Near Field Communication (NFC). Exemplary wireless networks include, but are not limited to, wireless local area networks, wireless personal area networks, wireless metropolitan area networks, cellular networks, and satellite networks.

I/O system 750 may be configured to interface between various I/O devices and other components of platform 700. I/O devices may include, but not be limited to, user interface 760 and display element 764. User interface 760 may include devices (not shown) such as a touchpad, cockpit display unit, keyboard, and mouse, etc., for example, to allow the user to control the system. Display element 764 may be configured to display information to a user. I/O system 750 may include a graphics subsystem configured to perform processing of images for rendering on the display element 764. Graphics subsystem may be a graphics processing unit or a visual processing unit (VPU), for example. An analog or digital interface may be used to communicatively couple graphics subsystem and the display element. For example, the interface may be any of a high definition multimedia interface (HDMI), DisplayPort, wireless HDMI, and/or any other suitable interface using wireless high definition compliant techniques. In some embodiments, the graphics subsystem could be integrated into processor 710 or any chipset of platform 700.

It will be appreciated that in some embodiments, the various components of platform 700 may be combined or integrated in a system-on-a-chip (SoC) architecture. In some embodiments, the components may be hardware components, firmware components, software components or any suitable combination of hardware, firmware, or software.

Scanning RF filter 110 is configured to rapidly sweep a filter over a wide bandwidth, for transmission or reception of RF signals, as described previously. Scanning RF filter 110 may include any or all of the circuits/components illustrated in FIGS. 1 and 2, as described above. These components can be implemented or otherwise used in conjunction with a variety of suitable software and/or hardware that is coupled to or that otherwise forms a part of platform 700. These components can additionally or alternatively be implemented or otherwise used in conjunction with user I/O devices that are capable of providing information to, and receiving information and commands from, a user.

In various embodiments, platform 700 may be implemented as a wireless system, a wired system, or a combination of both. When implemented as a wireless system, platform 700 may include components and interfaces suitable for communicating over a wireless shared media, such as one or more antennae, transmitters, receivers, transceivers, amplifiers, filters, control logic, and so forth. An example of wireless shared media may include portions of a wireless spectrum, such as the radio frequency spectrum and so forth. When implemented as a wired system, platform 700 may include components and interfaces suitable for communicating over wired communications media, such as input/output adapters, physical connectors to connect the input/output adaptor with a corresponding wired communications medium, a network interface card (NIC), disc controller, video controller, audio controller, and so forth. Examples of wired communications media may include a wire, cable metal leads, printed circuit board (PCB), backplane, switch fabric, semiconductor material, twisted pair wire, coaxial cable, fiber optics, and so forth.

Various embodiments may be implemented using hardware elements, software elements, or a combination of both. Examples of hardware elements may include processors, microprocessors, circuits, circuit elements (for example, transistors, resistors, capacitors, inductors, and so forth), integrated circuits, ASICs, programmable logic devices, digital signal processors, FPGAs, logic gates, registers, semiconductor devices, chips, microchips, chipsets, and so forth. Examples of software may include software components, programs, applications, computer programs, application programs, system programs, machine programs, operating system software, middleware, firmware, software modules, routines, subroutines, functions, methods, procedures, software interfaces, application program interfaces, instruction sets, computing code, computer code, code segments, computer code segments, words, values, symbols, or any combination thereof. Determining whether an embodiment is implemented using hardware elements and/or software elements may vary in accordance with any number of factors, such as desired computational rate, power level, heat tolerances, processing cycle budget, input data rates, output data rates, memory resources, data bus speeds, and other design or performance constraints.

Some embodiments may be described using the expression “coupled” and “connected” along with their derivatives. These terms are not intended as synonyms for each other. For example, some embodiments may be described using the terms “connected” and/or “coupled” to indicate that two or more elements are in direct physical or electrical contact with each other. The term “coupled,” however, may also mean that two or more elements are not in direct contact with each other, but yet still cooperate or interact with each other.

The various embodiments disclosed herein can be implemented in various forms of hardware, software, firmware, and/or special purpose processors. For example, in one embodiment at least one non-transitory computer readable storage medium has instructions encoded thereon that, when executed by one or more processors, cause one or more of the methodologies disclosed herein to be implemented. The instructions can be encoded using a suitable programming language, such as C, C++, object oriented C, Java, JavaScript, Visual Basic .NET, Beginner's All-Purpose Symbolic Instruction Code (BASIC), or alternatively, using custom or proprietary instruction sets. The instructions can be provided in the form of one or more computer software applications and/or applets that are tangibly embodied on a memory device, and that can be executed by a computer having any suitable architecture. In one embodiment, the system can be hosted on a given website and implemented, for example, using JavaScript or another suitable browser-based technology. For instance, in certain embodiments, the system may leverage processing resources provided by a remote computer system accessible via network 794. The computer software applications disclosed herein may include any number of different modules, sub-modules, or other components of distinct functionality, and can provide information to, or receive information from, still other components. These modules can be used, for example, to communicate with input and/or output devices such as a display screen, a touch sensitive surface, a printer, and/or any other suitable device. Other componentry and functionality not reflected in the illustrations will be apparent in light of this disclosure, and it will be appreciated that other embodiments are not limited to any particular hardware or software configuration. Thus, in other embodiments platform 700 may comprise additional, fewer, or alternative subcomponents as compared to those included in the example embodiment of FIG. 7.

The aforementioned non-transitory computer readable medium may be any suitable medium for storing digital information, such as a hard drive, a server, a flash memory, and/or random-access memory (RAM), or a combination of memories. In alternative embodiments, the components and/or modules disclosed herein can be implemented with hardware, including gate level logic such as a field-programmable gate array (FPGA), or alternatively, a purpose-built semiconductor such as an application-specific integrated circuit (ASIC). Still other embodiments may be implemented with a microcontroller having a number of input/output ports for receiving and outputting data, and a number of embedded routines for carrying out the various functionalities disclosed herein. It will be apparent that any suitable combination of hardware, software, and firmware can be used, and that other embodiments are not limited to any particular system architecture.

Some embodiments may be implemented, for example, using a machine readable medium or article which may store an instruction or a set of instructions that, if executed by a machine, may cause the machine to perform a method, process, and/or operations in accordance with the embodiments. Such a machine may include, for example, any suitable processing platform, computing platform, computing device, processing device, computing system, processing system, computer, process, or the like, and may be implemented using any suitable combination of hardware and/or software. The machine readable medium or article may include, for example, any suitable type of memory unit, memory device, memory article, memory medium, storage device, storage article, storage medium, and/or storage unit, such as memory, removable or non-removable media, erasable or non-erasable media, writeable or rewriteable media, digital or analog media, hard disk, floppy disk, compact disk read only memory (CD-ROM), compact disk recordable (CD-R) memory, compact disk rewriteable (CD-RW) memory, optical disk, magnetic media, magneto-optical media, removable memory cards or disks, various types of digital versatile disk (DVD), a tape, a cassette, or the like. The instructions may include any suitable type of code, such as source code, compiled code, interpreted code, executable code, static code, dynamic code, encrypted code, and the like, implemented using any suitable high level, low level, object oriented, visual, compiled, and/or interpreted programming language.

Unless specifically stated otherwise, it may be appreciated that terms such as “processing,” “computing,” “calculating,” “determining,” or the like refer to the action and/or process of a computer or computing system, or similar electronic computing device, that manipulates and/or transforms data represented as physical quantities (for example, electronic) within the registers and/or memory units of the computer system into other data similarly represented as physical entities within the registers, memory units, or other such information storage transmission or displays of the computer system. The embodiments are not limited in this context.

The terms “circuit” or “circuitry,” as used in any embodiment herein, are functional and may comprise, for example, singly or in any combination, hardwired circuitry, programmable circuitry such as computer processors comprising one or more individual instruction processing cores, state machine circuitry, and/or firmware that stores instructions executed by programmable circuitry. The circuitry may include a processor and/or controller configured to execute one or more instructions to perform one or more operations described herein. The instructions may be embodied as, for example, an application, software, firmware, etc. configured to cause the circuitry to perform any of the aforementioned operations. Software may be embodied as a software package, code, instructions, instruction sets and/or data recorded on a computer-readable storage device. Software may be embodied or implemented to include any number of processes, and processes, in turn, may be embodied or implemented to include any number of threads, etc., in a hierarchical fashion. Firmware may be embodied as code, instructions or instruction sets and/or data that are hard-coded (e.g., nonvolatile) in memory devices. The circuitry may, collectively or individually, be embodied as circuitry that forms part of a larger system, for example, an integrated circuit (IC), an application-specific integrated circuit (ASIC), a system-on-a-chip (SoC), desktop computers, laptop computers, tablet computers, servers, smartphones, etc. Other embodiments may be implemented as software executed by a programmable control device. In such cases, the terms “circuit” or “circuitry” are intended to include a combination of software and hardware such as a programmable control device or a processor capable of executing the software. As described herein, various embodiments may be implemented using hardware elements, software elements, or any combination thereof. Examples of hardware elements may include processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, chip sets, and so forth.

Numerous specific details have been set forth herein to provide a thorough understanding of the embodiments. It will be understood, however, that other embodiments may be practiced without these specific details, or otherwise with a different set of details. It will be further appreciated that the specific structural and functional details disclosed herein are representative of example embodiments and are not necessarily intended to limit the scope of the present disclosure. In addition, although the subject matter has been described in language specific to structural features and/or methodological acts, it is to be understood that the subject matter defined in the appended claims is not necessarily limited to the specific features or acts described herein. Rather, the specific features and acts described herein are disclosed as example forms of implementing the claims.

### Further Example Embodiments

The following examples pertain to further embodiments, from which numerous permutations and configurations will be apparent.
Example 1 is a circuit comprising: a magnetostatic wave filter configured to filter a signal at a sweeping resonant frequency, the resonant frequency based on an applied magnetic flux density; and a filter modulator comprising a voltage sweep generator configured to generate a periodic time varying voltage, and an electromagnet coupled in series with the voltage sweep generator and configured to generate the magnetic flux density based on a current flow through an inductive component of the electromagnet, the current flow proportional to the periodic time varying voltage.
Example 2 includes the circuit of Example 1, wherein the magnetostatic wave filter is a planar device comprising a ferrimagnetic material including magnetite, yttrium iron garnet, or rhenium ferrite.
Example 3 includes the circuit of Example 2, wherein the planar device is a thin film device having a thickness of less than 10 micrometers.
Example 4 includes the circuit of any of Examples 1-3, wherein a rate of change of the magnetic flux density is in the range of 0.1 tesla per microsecond to 1.1 tesla per microsecond.
Example 5 includes the circuit of any of Examples 1-4, wherein the periodic time varying voltage is a non-sinusoidal waveform.
Example 6 includes the circuit of any of Examples 1-5, wherein a scan rate of the sweeping resonant frequency is based on an inductance of the electromagnet, an amplitude of the periodic time varying voltage, and a frequency of the periodic time varying voltage.
Example 7 includes the circuit of any of Examples 1-6, wherein the magnetic flux density is applied in an orthogonal direction relative to a plane of resonance of the magnetostatic wave filter.
Example 8 includes the circuit of any of Examples 1-7, wherein the magnetostatic wave filter is separated from the filter modulator by less than 100 micrometers.
Example 9 is a system comprising: an antenna configured to receive a radio frequency (RF) signal; a magnetostatic wave filter configured to filter the RF signal at a sweeping resonant frequency, the resonant frequency based on an applied magnetic flux density; a filter modulator comprising a voltage sweep generator configured to generate a periodic time varying voltage, and an electromagnet coupled in series with the voltage sweep generator and configured to generate the magnetic flux density based on a current flow through an inductive component of the electromagnet, the current flow proportional to the periodic time varying voltage; and an amplifier configured to amplify the filtered RF signal.
Example 10 includes the system of Example 9, wherein the magnetostatic wave filter is a planar device comprising a ferrimagnetic material including magnetite, yttrium iron garnet, or rhenium ferrite.
Example 11 includes the system of Example 10, wherein the planar device is a thin film device having a thickness of less than 10 micrometers.
Example 12 includes the system of any of Examples 9-11, wherein a rate of change of the magnetic flux density is in the range of 0.1 tesla per microsecond to 1.1 tesla per microsecond.
Example 13 includes the system of any of Examples 9-12, wherein the periodic time varying voltage is a non-sinusoidal waveform.
Example 14 includes the system of any of Examples 9-13, wherein a scan rate of the sweeping resonant frequency is based on an inductance of the electromagnet, an amplitude of the periodic time varying voltage, and a frequency of the periodic time varying voltage.
Example 15 includes the system of any of Examples 9-14, wherein the magnetic flux density is applied in an orthogonal direction relative to a plane of resonance of the magnetostatic wave filter.
Example 16 includes the system of any of Examples 9-15, wherein the magnetostatic wave filter is separated from the filter modulator by less than 100 micrometers.
Example 17 is a method comprising: configuring a magnetostatic wave filter to filter a signal at a sweeping resonant frequency, the resonant frequency based on an applied magnetic flux density; configuring a filter modulator to include a voltage sweep generator configured to generate a periodic time varying voltage and an electromagnet coupled in series with the voltage sweep generator and configured to generate the magnetic flux density based on a current flow through an inductive component of the electromagnet, the current flow proportional to the periodic time varying voltage; and disposing the filter modulator adjacent to the magnetostatic wave filter; wherein a scan rate of the sweeping resonant frequency is based on an inductance of the electromagnet, an amplitude of the periodic time varying voltage, and a frequency of the periodic time varying voltage.
Example 18 includes the method of Example 17, comprising fabricating the magnetostatic wave filter as a planar device comprising a ferrimagnetic material including magnetite, yttrium iron garnet, or rhenium ferrite.
Example 19 includes the method of Example 18, wherein the planar device is a thin film device having a thickness of less than 10 micrometers.
Example 20 includes the method of any of Examples 17-19, wherein the magnetostatic wave filter is separated from the filter modulator by less than 100 micrometers.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents. Various features, aspects, and embodiments have been described herein. The features, aspects, and embodiments are susceptible to combination with one another as well as to variation and modification, as will be appreciated in light of this disclosure. The present disclosure should, therefore, be considered to encompass such combinations, variations, and modifications. It is intended that the scope of the present disclosure be limited not by this detailed description, but rather by the claims appended hereto. Future filed applications claiming priority to this application may claim the disclosed subject matter in a different manner and may generally include any set of one or more elements as variously disclosed or otherwise demonstrated herein.

What is claimed is:

1. A circuit comprising:
a magnetostatic wave filter configured to filter a signal at a sweeping resonant frequency, the resonant frequency based on an applied magnetic flux density; and
a filter modulator comprising
a voltage sweep generator configured to generate a periodic time varying voltage, and
an electromagnet coupled in series with the voltage sweep generator and configured to generate the magnetic flux density based on a current flow through an inductive component of the electromagnet, the current flow proportional to the periodic time varying voltage.

2. The circuit of claim 1, wherein the magnetostatic wave filter is a planar device comprising a ferrimagnetic material including magnetite, yttrium iron garnet, or rhenium ferrite.

3. The circuit of claim 2, wherein the planar device is a thin film device having a thickness of less than 10 micrometers.

4. The circuit of claim 1, wherein a rate of change of the magnetic flux density is in the range of 0.1 tesla per microsecond to 1.1 tesla per microsecond.

5. The circuit of claim 1, wherein the periodic time varying voltage is a non-sinusoidal waveform.

6. The circuit of claim 1, wherein a scan rate of the sweeping resonant frequency is based on an inductance of the electromagnet, an amplitude of the periodic time varying voltage, and a frequency of the periodic time varying voltage.

7. The circuit of claim 1, wherein the magnetic flux density is applied in an orthogonal direction relative to a plane of resonance of the magnetostatic wave filter.

8. The circuit of claim 1, wherein the magnetostatic wave filter is separated from the filter modulator by less than 100 micrometers.

9. A system comprising:
an antenna configured to receive a radio frequency (RF) signal;
a magnetostatic wave filter configured to filter the RF signal at a sweeping resonant frequency, the resonant frequency based on an applied magnetic flux density;
a filter modulator comprising
a voltage sweep generator configured to generate a periodic time varying voltage, and
an electromagnet coupled in series with the voltage sweep generator and configured to generate the magnetic flux density based on a current flow through an inductive component of the electromagnet, the current flow proportional to the periodic time varying voltage; and
an amplifier configured to amplify the filtered RF signal.

10. The system of claim 9, wherein the magnetostatic wave filter is a planar device comprising a ferrimagnetic material including magnetite, yttrium iron garnet, or rhenium ferrite.

11. The system of claim 10, wherein the planar device is a thin film device having a thickness of less than 10 micrometers.

12. The system of claim 9, wherein a rate of change of the magnetic flux density is in the range of 0.1 tesla per microsecond to 1.1 tesla per microsecond.

13. The system of claim 9, wherein the periodic time varying voltage is a non-sinusoidal waveform.

14. The system of claim 9, wherein a scan rate of the sweeping resonant frequency is based on an inductance of the electromagnet, an amplitude of the periodic time varying voltage, and a frequency of the periodic time varying voltage.

15. The system of claim 9, wherein the magnetic flux density is applied in an orthogonal direction relative to a plane of resonance of the magnetostatic wave filter.

16. The system of claim 9, wherein the magnetostatic wave filter is separated from the filter modulator by less than 100 micrometers.

17. A method comprising:
configuring a magnetostatic wave filter to filter a signal at a sweeping resonant frequency, the resonant frequency based on an applied magnetic flux density;
configuring a filter modulator to include a voltage sweep generator configured to generate a periodic time varying voltage and an electromagnet coupled in series with the voltage sweep generator and configured to generate the magnetic flux density based on a current flow through an inductive component of the electromagnet, the current flow proportional to the periodic time varying voltage; and
disposing the filter modulator adjacent to the magnetostatic wave filter;
wherein a scan rate of the sweeping resonant frequency is based on an inductance of the electromagnet, an amplitude of the periodic time varying voltage, and a frequency of the periodic time varying voltage.

18. The method of claim 17, comprising fabricating the magnetostatic wave filter as a planar device comprising a ferrimagnetic material including magnetite, yttrium iron garnet, or rhenium ferrite.

19. The method of claim 18, wherein the planar device is a thin film device having a thickness of less than 10 micrometers.

20. The method of claim 17, wherein the magnetostatic wave filter is separated from the filter modulator by less than 100 micrometers.
